(19) United States
(12) Patent Application Publication
(10) Pub. No.: US 2026/0223345 A1
(43) Pub. Date: Jul. 30, 2026

(54) REAL-TIME PCBA MONITORING AND ALERT SYSTEM

(71) Applicant: CYBORD LTD., Tel Aviv (IL)

(72) Inventor: Eyal Isachar Weiss, Bnei Reem (IL)

(21) Appl. No.: 19/157,359

(22) PCT Filed: Feb. 22, 2024
(86) PCT No.: PCT/IL2024/050206

§ 371 Date: Aug. 17, 2025

Related U.S. Application Data
(60) Provisional application No. 63/447,774, filed on Feb. 23, 2023.

(51) Int. Cl. H05K 13/08; H05K 13/04

(52) U.S. Cl. CPC H05K 13/083; H05K 13/0404; H05K 13/0812; H05K 13/0817; H05K 13/089

(57) ABSTRACT

A system for real-time monitoring of a PCBA assembly line comprising a plurality of assembly stations, the system comprising: at least one imaging system for each assembly station of the plurality of assembly stations operable to acquire an assembly station image of a PCBA being assembled at the assembly station; and at least one processing system configured to process the assembly station image acquired for the PCBA to generate a real-time quality of product (QoP) feature vector, QoP-FV, having at least one real-time component that provides a real-time indication of quality for a feature of the PCBA for a time substantially at a time for which the PCBA is at the assembly station.

### RELATED APPLICATIONS

The present application claims the benefit under 35 U.S.C. 119(e) of U.S. Provisional Application 63/447,774 filed on Feb. 23, 2023, the disclosure of which is incorporated herein by reference.

### FIELD

Embodiments of the invention relate to providing quality of product (QoP) measures for printed circuit broad assemblies (PCBAs) and using QoP measures for monitoring and controlling equipment in PCBA assembly lines and providing enhanced traceability data for PCBAs assembled by the assembly lines

### BACKGROUND

Quality control and traceability are bedrock partner technologies that underpin the safe and reliable operation of the complex devices and systems that color, if not determine, almost every aspect of modern human activity that includes, by way of example, modern forms of play, communications, transportation, management, biotechnology, and medicine.

For the electronics industry that produces, configures, and assembles the ever-present electronic circuits that provide, support, and format the devices and systems that support modern activity, quality control may be provided by automatic or manual visual inspection of the circuits and assembly of the circuits. Traceability may be provided by storing data responsive to the inspection in logistical logs.

In the highly automated, predominant technology for manufacturing electronic circuits referred to as surface mounted technology (SMT), electronic components are assembled on printed circuit boards (PCBs) by pick and place robots (P&Ps) installed at various assembly stations of a PCB circuit assembly line. The components are provided in packaging units (PUs) generally in the form of reels, trays, stick magazines, or bulk, that are configured ready for mounting to or access by the P&P robots. The robots remove the components from the PUs and carefully position the components at their designated locations on conductive PCB traces formed on the PCBs so that conductive leads of the components are in contact with the traces. Following positioning of the components on the traces, the components are fixed and electrically connected to the traces by a soldering process, such as a reflow soldering process. The finished electronic circuits are conventionally referred to as PCB assemblies and typically by the acronym PCBA.

Quality control and traceability data for the PCBAs produced by PCBA assembly lines are acquired by automatic imaging systems comprised in the assembly lines that image placement of the electronic components on the PCBs and read logistical data labeling and/or associated with the components and the PUs. Acquisition and management of the data is complex and constantly challenged by demand for increased rates of production and development of new varieties of PCBAs.

### SUMMARY

An aspect of an embodiment of the disclosure relates to providing methods and devices for providing a real-time, dynamically self-adjusting system, optionally referred to as a Dynamic-QoP (Quality of Product) system or simply Dynamic-QoP, for monitoring a PCBA assembly line to acquire high resolution QoP data for PCBAs assembled by the assembly line. The QoP data provides real-time measures of quality of the PCBAs during their assembly. In an embodiment the QoP data is used to control hardware and/or software components of the Dynamic-QoP and/or the PCBA assembly line to improve in real-time the quality of data that the Dynamic-QoP acquires and/or operation of the PCBA assembly line. In an embodiment the QoP data is stored to provide traceability data and may be used to alert, optionally in real-time, a user to a quality issue associated with the PCBAs and/or operation of the PCBA assembly line.

Dynamic-QoP is configured to acquire at least one image, also referred to as an assembly station image, of a PCBA being assembled by the PCBA assembly line at each of a plurality of different assembly stations comprised in the assembly line during assembly of the PCBA. An image of a PCBA being assembled at an assembly station refers to an image of at least one component of the PCBA while the PCBA is located at the assembly station or an image of the at least one component of the PCBA acquired after the PCBA has exited the assembly station from which the image of the PCBA while located in the assembly station may be inferred. In an embodiment the at least one assembly station image may be acquired using any of various imaging modalities such as by way of example, 2D imaging, 3D imaging, IR imaging, and/or X-ray imaging. Dynamic-QoP processes the at least one assembly station image to generate QoP data for the PCBA, optionally in real-time, that is associated with status and thereby quality of assembly of the PCBA at the assembly station.

In an embodiment, real-time refers to a time that follows an event at the PCBA assembly line by a time lapse that is less than a time for a PCBA that the assembly line assembles to traverse the assembly line from a first to a last assembly station of the assembly line. Real-time data is valid data for an event at the PCBA assembly line that is accessible within a time lapse from the time of the event that is less than a time for a PCBA to traverse from a first to a last assembly station of the assembly line. Optionally, the time lapse is less than a transit time of the PCB from a given assembly station to a next subsequent assembly station in the assembly line.

In an embodiment the QoP data comprises a set, referred to as a QoP feature vector, QoP-FV, comprising a plurality of components QoP_{q} (1≤q≤Q) that provide respective real-time indications of quality for different features of the PCBA. In symbols QoP-FV ={QoP_{q}|1≤q≤Q}. Dynamic-QoP may operate to determine a first feature vector, QoP-FV for a PCBA at a first assembly station responsive to a second feature vector QoP-FV determined for the PCBA at a second assembly station.

In an embodiment determining the first QoP-FV responsive to the second QoP-FV may comprise: 1) modifying Dynamic-QoP and/or assembly line equipment at the first assembly station responsive to the second QoP-FV to acquire a first assembly station image of the PCBA at the first assembly station; 2) modifying an algorithm that processes a first assembly station image of the PCBA acquired at the first assembly station responsive to the second QoP-FV; and/or 3) using a same algorithm used to process a second assembly station image to process a first assembly station image responsive to the second QoP-FV.

By way of example, modifying Dynamic-QoP equipment may comprise modifying intrinsic or extrinsic parameters of a camera system that acquires an assembly station image of the PCBA. Modifying assembly line equipment may comprise modifying velocity with which a P&P removes an electronic component from a PU and places the component on the PCB on which the PCBA is assembled. Modifying an algorithm may comprise adjusting hyperparameters of the algorithm. And processing using a same algorithm may comprise using data from the second QoP-FV as input data to the algorithm that processes the assembly station image from the first assembly line station.

Determining the first QoP-FV responsive to the second QoP-FV may operate to improve quality and resolution of the first QoP-FV for use in detecting and identifying defective features that may injure or limit functioning and/or longevity of the PCBA. The defective features may by way of example include corrosion or physical damage to leads of electronic components of the PCBA that are mounted to conductive traces of the PCB comprised in the PCBA, faulty PCB traces, and/or aberrant deviations in pose of electronic components placed on the traces.

In an embodiment, Dynamic-QoP is configured to generate control signals responsive to QoP-FVs that Dynamic-QoP determines for controlling equipment comprised in the PCBA assembly line that cooperate to assemble a PCBA. Controlling PCBA assembly line equipment may include controlling operation of P&P robots, intrinsic and extrinsic parameters of automatic optical inspection (AOI) cameras, and temperature of a reflow oven in the assembly line.

A Dynamic-QoP may comprise and/or have access to any combination of processing and storage hardware and data and/or executable instructions and any suitable configuration thereof for processing assembly station images to generate QoP data and support functionalities that the Dynamic-QoP provides. The configuration of data and/or executable instructions, hereinafter referred to as software, and hardware may be at least partially cloud based.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE FIGURES

Non-limiting examples of embodiments of the disclosure are described below with reference to figures attached hereto that are listed following this paragraph. Identical features that appear in more than one figure are generally labeled with a same label in all the figures in which they appear. A label labeling an icon representing a given feature in a figure of an embodiment of the disclosure may be used to reference the given feature. Dimensions of features shown in the figures are chosen for convenience and clarity of presentation and are not necessarily shown to scale.

FIGS. 1A and 1B schematically show a Dynamic-QoP monitoring an SMT assembly line assembling a PCBA, in accordance with an embodiment of the disclosure.

### DETAILED DESCRIPTION

In the discussion, unless otherwise stated, adjectives such as “substantially” and “about” modifying a condition or relationship characteristic of a feature or features of an embodiment of the disclosure, are understood to mean that the condition or characteristic is defined to within tolerances that are acceptable for operation of the embodiment in an application for which it is intended. Wherever a general term in the disclosure is illustrated by reference to an example instance or a list of example instances, the instance or instances referred to, are by way of non-limiting example instances of the general term, and the general term is not intended to be limited to the specific example instance or instances referred to. The phrase “in an embodiment”, whether or not associated with a permissive, such as “may”, “optionally”, or “by way of example”, is used to introduce for consideration an example, but not necessarily required, configuration of possible embodiments of the disclosure. Each of the verbs, “comprise” “include” and “have”, and conjugates thereof, are used to indicate that the object or objects of the verb are not necessarily a complete listing of components, elements or parts of the subject or subjects of the verb. Unless otherwise indicated, the word “or” in the description and claims is considered to be the inclusive “or” rather than the exclusive or, and indicates at least one of, or any combination of more than one of items it conjoins.

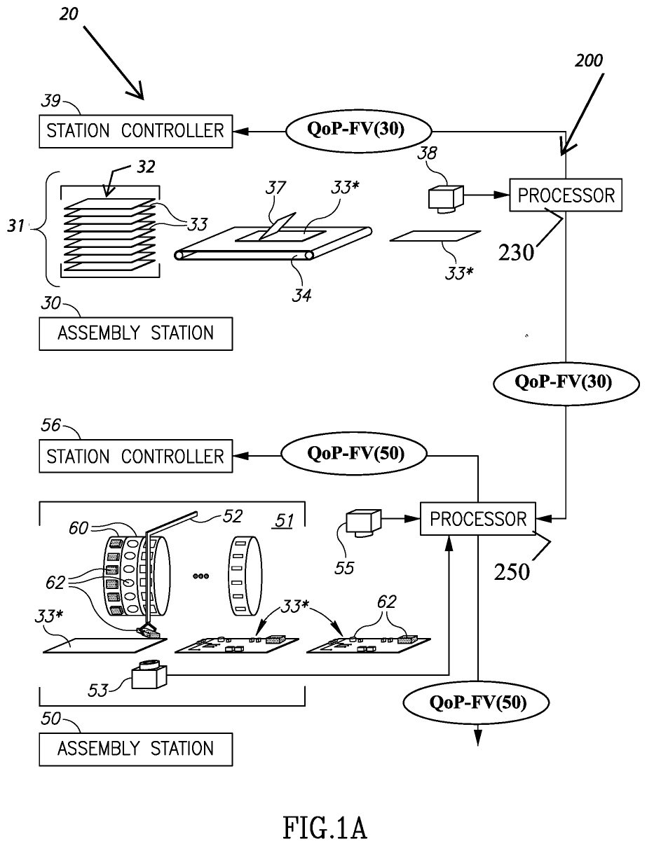

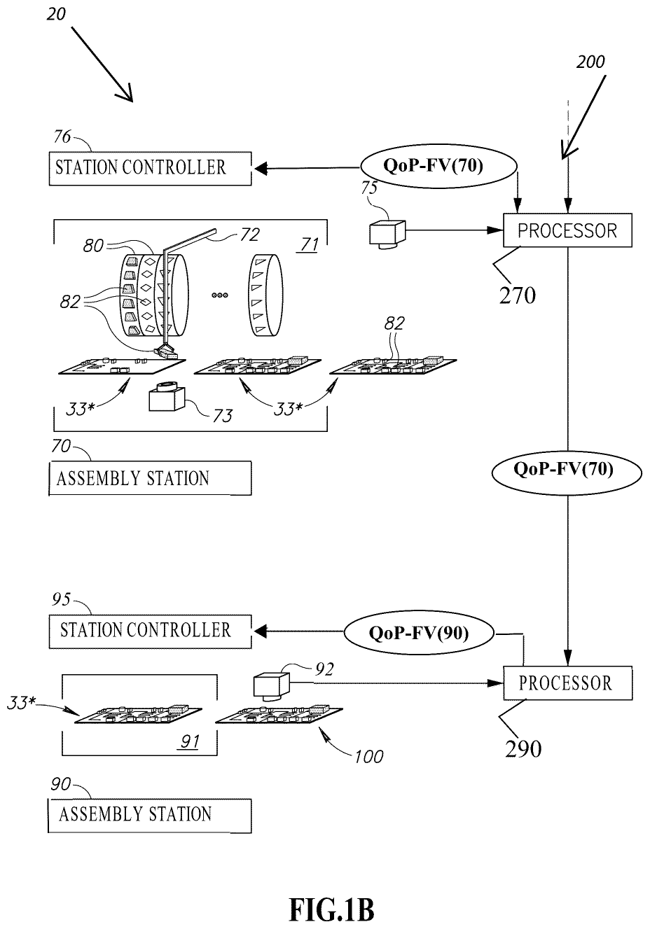

FIGS. 1A and 1B show a very schematic illustration of an SMT PCBA assembly line 20 assembling a PCBA 100 (shown in FIG. 1B) and a Dynamic-QoP system 200 monitoring the SMT assembly line and determining and using QoP data for the PCBA to facilitate functioning of the assembly line, in accordance with an embodiment of the disclosure.

SMT assembly line 20 optionally comprises by way of example four assembly stations: a solder screen printing assembly station 30 schematically shown in FIG. 1A; P&P assembly stations 50 and 70 schematically shown in FIGS. 1A and 1B respectively; and a reflow soldering assembly station 90 schematically shown in FIG. 1B that is a last assembly station in SMT assembly line 20.

Screen printing assembly station 30 optionally comprises a PCB line loader 31 shown supplied with a stack 32 of PCBs 33 printed with a pattern of conductive traces (not shown), a conveyor belt 34, and a screen printer represented by a squeegee 37. Conveyor belt 34 receives PCBs 33 from line loader 31 and moves received PCBs 33 through screen printer 37, which prints a pattern of solder (not shown) matching and overlaying the pattern of conductive traces printed on the PCBs. After screen printing, conveyor 34 moves a screen-printed PCB 33 through a field of view (FOV) of an automatic optical inspection (AOI) camera 38 to be imaged by the camera for quality control inspection and on to P&P assembly station 50. A station controller 39 controls the loader, conveyor belt, and screen printer.

FIG. 1A schematically shows assembly station 30 screen printing and inspecting a particular PCB 33*, on which electronic components of PCBA 100 are to be assembled at P&P assembly stations 50 and 70. The fully assembled PCBA 100 is shown at a final assembly station 90.

P&P assembly station 50 comprises a P&P robot 51 assumed to be configured to receive electronic components for positioning on PCBs from component reels and the P&P robot is shown loaded with a plurality of component reels 60 comprising a variety of electronic components 62 that are to be assembled on screen printed PCBs 33 that assembly station 50 receives from assembly station 30. P&P robot 51 comprises a P&P robotic arm 52 for removing components 62 from reels 60 and placing the components on screen printed PCB boards 33 received from assembly station 30 and an operations camera 53 for assisting and monitoring operation of the P&P robot. Operations camera 53 is configured and posed to acquire an image of a bottom of a component 62 that P&P robot 52 removes from a reel 60 to place on a PCB 33. P&P robot 51 uses the image to properly position the component so that leads (not shown) of the component are accurately positioned to contact a trace or traces on the PCB to which the component is intended to make electrical contact.

Following positioning of components that assembly station 50 is tasked with assembling on a PCB 33 the assembled PCB is moved through a FOV of an AOI camera 55 to be imaged for quality control inspection by the camera. It is assumed by way of example that that assembly station 50 is tasked with assembling only a portion of a complement of electronic components required by a completely assembled PCBA on a PCB and following imaging by AOI 55 PCB 33 and its partial complement of electronic components is moved to P&P assembly station 70 for positioning additional electronic components on the PCB. A station controller 56 controls P&P robot 51 and conveyor belts (not shown) that move PCBs 33 through the assembly station.

FIG. 1A shows, P&P assembly station 50 after having received PCB 33* from assembly station 30 and robotic arm 52 positioning an electronic component 62 on PCB 33*. Since it is assumed as noted above that assembly station 50 is tasked with assembling only a portion of the component of electronic components required by PCBA 100, PCB 33* is shown leaving P&P robot 51 with only a portion of the electronic components comprised by PCBA 100 and being subsequently imaged by AOI camera 55 prior to forwarding to P&P assembly station 70 shown in FIG. 1B.

P&P assembly station 70 is similar to assembly station 50 and optionally comprises a P&P robot 71 having a robot arm 72, an operations camera 73, an AOI camera 75 and a station controller 76. P&P assembly station 70 is loaded with electronic component reels 80 having electronic components 82 to be positioned on a partially complemented PCB 33 received from assembly station 50 to complete a compliment of electronic components required for a PCBA produced by SMT assembly line 20.

In FIG. 1B P&P robotic arm 72 is shown positioning a component 82 onto PCB 33* received from assembly station 50 to complete the complement of electronic components required by PCBA 100. PCB 33* is shown at assembly station 70 with a full complement of electronic components 62 and 82 after leaving P&P robot 71 to be imaged for quality control by AOI camera 75 before being conveyed to reflow assembly station 90.

Reflow assembly station 90 comprises a reflow oven 91 in which PCBs 33 fully complimented with electronics components is heated to solder contact leads of the components to the solder pattern screen printed on the PCBs at assembly station 30 and complete production of PCBAs comprising the PCBs. Following reflow soldering in reflow oven 91 a fully assembled and completed PCBA is imaged for quality control by an AOI camera 92. A station controller 95 controls the reflow oven and optionally AOI camera 92 FIG. 1B schematically shows assembly station 90 processing PCB 33* received from P&P assembly station 70 and transporting PCB 33* through reflow oven 91 to solder components on PCB 33* to the solder pattern screen printed on PCB 33* and complete production of PCBA 100. PCBA 100 is shown being imaged by AOI camera 92.

In an embodiment Dynamic-QoP 200 comprises at least one imaging system at each SMT 20 assembly station 30, 50, 70, and 90 operable to acquire an assembly station image, of a PCBA at the assembly station during assembly of the PCBA. The Dynamic-QoP 200 comprises at least one, optionally cloud based, processing system operable to communicate with the at least one imaging system to receive and process an assembly station image of the PCBA acquired by the at least one imaging system. In FIGS. 1A and 1B the at least one processing system is schematically represented by processors 230, 250, 270, and 290. It is noted however, that whereas FIG. 1 shows Dynamic-QoP 200 comprising a different processor for each assembly station, a Dynamic-QoP in accordance with an embodiment may comprise a single processing system which provides all of the various functionalities provided by processors 230, 250, 270, and 290 described below. Optionally, the at least one imaging system at each assembly station comprises at least one camera and/or other imaging system that is normally used to facilitate and provide conventional quality control of processes performed by the assembly stations. By way of example the at least one imaging system comprised by Dynamic-QoP 200 for assembly station 30 includes AOI 38. And the at least one imaging system comprised by Dynamic-QoP 200 for assembly station 50 includes operational camera 53 and AOI camera 55.

Processors 230, 250, 270 and 290 operate to receive and process assembly station images respectively acquired for assembly stations 30, 50, 70, and 90 comprised in PCBA assembly line 20. Each processor processes at least one assembly station image that it receives from an assembly station for a PCBA undergoing an assembly procedure at the assembly station optionally to generate a QoP feature vector, QoP-FV. The QoP-FV, provides at least one measure responsive to quality of components and assembly of the PCBA, and/or operation of the assembly station for a time substantially at a time for which the PCBA is at the assembly station. The QoP-FV, may comprise a plurality of feature vector quality components QoP_{q} (1≤q≤Q) that provide indications of quality for different features of the PCBA at the assembly station and/or operation of the assembly station.

A feature component QoP_{q} for the PCBA may by way of example, indicate a degree of quality for such features as physical integrity and/or corrosion of conductive traces on a PCB of the PCBA, quality of physical integrity of each of a plurality of electrical components of the PCBA, accuracy of position with which an electrical component is positioned on a conductive trace, quality of reflow soldering of electrical components, and/or quality of an assembly station image responsive to which the QoP-FV is generated. A feature component QoP_{q} indicative of operation of the assembly station, may be a key performance indicator, KPI_{q}, that indicates status and/or quality of performance of the assembly station in executing tasks for which the assembly station is configured to perform. By way of example a KPI_{q} may indicate an ambient temperature of the station, amplitude or frequency of vibrations of a component of the station, FOV and resolution of an AOI or operations camera of the station, and/or rate of P&P operations of the station.

Optionally a processor 230, 250, 270 and/or 290 generates control signals for controlling equipment comprised in the PCBA assembly line responsive to the QoP-FVs the processor generates.

In an embodiment, a processor 230, 250, 270, and/or 290 transmits QoP-FV feature vectors and/or control signals that it generates for a PCBA to the respective station controller 39, 56, 76, or 95 of the assembly station 30, 50, 70, and 90 with which the processor is associated. Optionally the processor transmits QoP-FV feature vectors and/or control signals that it generates to a processor associated with another assembly station that SMT 20 operates to assemble the PCBA. In an embodiment, a processor 230, 250, 270, and/or 290 generates QoP-FV feature vectors and/or control signals responsive not only to station images that the processor receives from its associated assembly station but also to QoP-FV feature vectors that it receives from another processor. Optionally, a processor 230, 250, 270, and/or 290 transmits station images that the processor receives from its associated assembly station to a processor 230, 250, 270, and/or 290 of another assembly station. In an embodiment a processor 230, 250, 270, and/or 290 generates QoP-FV feature vectors and/or control signals responsive to station images it receives from other processors.

In FIGS. 1A and 1B feature vectors QoP-FV and/or control signals generated by processors 230, 250, 270, and 290 responsive to assembly station images of a PCBA being assembled at assembly stations 30, 50, 70, and 90 respectively are represented by ellipses labeled QoP-FV(30), QoP-FV(50), QoP-FV(70), and QoP-FV(90). The ellipses are associated with arrows indicating to which controllers and next assembly stations the processors optionally transmit the feature vectors.

In an embodiment, a station controller 39, 56, 76, or 95 of an assembly station 30, 50, 70, or 90 that receives a QoP-FV feature vector and/or a control signal from its respective associated processor 230, 250, 270, or 290 or from another processor may control apparatus at the assembly station responsive to the QoP-FV feature vector and/or control signal to configure operation of the assembly station. In an embodiment Dynamic-QoP 200 may flag a user to undertake an action to intervene in operation of PCBA assembly line 20, for example to correct for a malfunction or perform a maintenance task for an assembly station 30, 50, 70, or 90, responsive to a value of a KPI or QoP comprised in a QoP-FV generated by a processor 230, 250, 270, or 290.

Optionally, Dynamic-QoP 200 processes QoP-FV feature vectors generated by processors 230, 250, 270, or 290 for PCBAs produced by PCBA assembly line 20 to provide for each of a plurality of the PCBAs a global quality of product, GQOP, that grades quality of the PCBA. The grades may by way of example, be indicative of a service lifetime and/or failure probability for the PCBA.

In an embodiment processors 230, 250, 270, or 290 process assembly station images they receive using any of various types of artificial intelligences (AIs), such as machine learning (ML) systems, neural networks, and/or natural language processors, to generate QoP-FV feature vectors and/or control signals.

There is therefore provided in accordance with an embodiment of the disclosure a system for real-time monitoring of a PCBA assembly line comprising a plurality of assembly stations, the system comprising: at least one imaging system for each assembly station of the plurality of assembly stations operable to acquire an assembly station image of a PCBA being assembled at the assembly station during assembly of the PCBA by the PCBA assembly line; and at least one processing system configured to process the assembly station image acquired for the PCBA to generate a real-time quality of product (QoP) feature vector, QoP-FV, having at least one real-time component that provides a real-time indication of quality for a feature of the PCBA for a time substantially at a time for which the PCBA is at the assembly station. Optionally the QoP-FV feature vector has at least one real-time key performance indicator (KPI) that provides an indication of status and/or quality of performance of the assembly station.

Additionally, or alternatively the at least one processing system optionally comprises instructions executable to generate the QoP-FV responsive to an assembly station image generated for another of the plurality of assembly stations. Optionally, the assembly station image generated for the other of the plurality of assembly stations is generated for the same PCBA. Optionally, the assembly the assembly station image generated for the other of the plurality of assembly stations is generated for a different PCBA.

In an embodiment, the at least one processing system comprises instructions executable to generate the QoP-FV responsive to an assembly station image generated for another PCBA assembled at the same assembly station.

In an embodiment, the at least one processing system comprises instructions executable to generate the QoP-FV responsive to a QoP-FV generated for another of the plurality of assembly stations. Optionally, the the QoP-FV generated for the other of the plurality of assembly stations is generated for the same PCBA. Optionally, the QoP-FV generated for the other of the plurality of assembly stations is generated for a different PCBA.

In an embodiment, the at least one processing system comprises instructions executable to generate the QoP-FV responsive to a QoP-FV generated for the same assembly station for a different PCBA.

In an embodiment, the at least one processing system comprises instructions executable to modify the instructions to generate the QoP-FV for the assembly station responsive to at least one or any combination of more than one of the QoP-FV, a different QoP-FV generated for the assembly station, and/or a QoP-FV generated for another of the plurality of assembly stations.

In an embodiment, the at least one processing system comprises instructions executable to modify the instructions to generate the QoP-FV for the assembly station responsive to at least one or any combination of more than one of the assembly station image, a different assembly station image acquired for the assembly station, and/or an assembly station image acquired for another of the plurality of assembly stations.

In an embodiment, the at least one processing system comprises instructions executable to generate a control signal for causing a modification of at least one assembly line equipment comprised in the assembly line station responsive to to at least one or any combination of more than one of the assembly station image, the QoP-FV, an assembly station image acquired for another of the plurality of assembly stations, and/or a QoP-FV generated by the processing system for another of the plurality of assembly stations. Optionally, the modification comprises a change in an intrinsic or extrinsic parameter of an imaging system of an assembly station of the plurality of assembly stations. Optionally, the plurality of assembly stations comprises a pick and place (P&P) assembly station, and the modification comprises a change in a rate of pick and place operations of the P&P assembly station of the plurality of assembly stations. Optionally, the plurality of assembly stations comprises a reflow oven and the modification comprises a change in an operating temperature of the oven.

In an embodiment the PCBA assembly line comprises a controller configured to use the real-time control signal to effectuate the modification and the controller and at least one processing system are configured to communicate and transmit the control signal from the at least one processing system to the controller. Optionally, the at least one processing system and the controller are configured to respectively generate and use the control signal to effectuate the modification before the PCBA moves along the assembly line arrives at the at least one assembly line equipment.

In an embodiment, the real time indication provided by the real-time component is accessible within a time lapse from a time of acquisition of the assembly station image processed to determine a value for the indication is less than a time for a PCBA that is assembled by the assembly line to traverse from a first to a last assembly station of the assembly line.

In an embodiment, the time lapse is less than a time for the PCBA to traverse to a first assembly station from a second assembly station from which the first assembly station receives the PCBA and wherein at least one of the first and second assembly stations is neither the first nor last assembly station of the PCBA assembly line. Optionally, the time lapse is less than a time it takes to traverse an assembly station of the plurality of assembly stations. Optionally, the time lapse is less than a time it takes a pick and place (P&P) robot in the PCBA assembly line to take an electronic component from a packaging unit (PU) and place the component on the PCBA. Optionally, the time lapse the time lapse is less than 5 milliseconds.

Descriptions of embodiments of the invention in the present application are provided by way of example and are not intended to limit the scope of the invention. The described embodiments comprise different features, not all of which are required in all embodiments of the invention. Some embodiments utilize only some of the features or possible combinations of the features. Variations of embodiments of the invention that are described, and embodiments of the invention comprising different combinations of features noted in the described embodiments, will occur to persons of the art. The scope of the invention is limited only by the claims.

1. A system for real-time monitoring of a PCBA assembly line comprising a plurality of assembly stations, the system comprising:
at least one imaging system for each assembly station of the plurality of assembly stations operable to acquire an assembly station image of a PCBA being assembled at the assembly station during assembly of the PCBA by the PCBA assembly line; and
at least one processing system configured to process the assembly station image acquired for the PCBA to generate a real-time quality of product (QoP) feature vector, QoP-FV, having at least one real-time component that provides a real-time indication of quality for a feature of the PCBA for a time substantially at a time for which the PCBA is at the assembly station.

2. The system according to claim 1 wherein the QoP-FV feature vector has at least one real-time key performance indicator (KPI) that provides an indication of status and/or quality of performance of the assembly station.

3. The system according to claim 1 wherein the at least one processing system comprises instructions executable to generate the QoP-FV responsive to an assembly station image generated for another of the plurality of assembly stations.

4. The system according to claim 3 wherein the assembly station image generated for the other of the plurality of assembly stations is generated for the same PCBA.

5. The system according to claim 3 wherein the assembly station image generated for the other of the plurality of assembly stations is generated for a different PCBA.

6. The system according to claim 1 wherein the at least one processing system comprises instructions executable to generate the QoP-FV responsive to an assembly station image generated for another PCBA assembled at the same assembly station.

7. The system according to claim 1 wherein the at least one processing system comprises instructions executable to generate the QoP-FV responsive to a QoP-FV generated for another of the plurality of assembly stations.

8. The system according to claim 7 wherein the QoP-FV generated for the other of the plurality of assembly stations is generated for the same PCBA.

9. The system according to claim 7 wherein the QoP-FV generated for the other of the plurality of assembly stations is generated for a different PCBA.

10. The system according to claim 1 wherein the at least one processing system comprises instructions executable to generate the QoP-FV responsive to a QoP-FV generated for the same assembly station for a different PCBA.

11. The system according to claim 1 wherein the at least one processing system comprises instructions executable to modify the instructions to generate the QoP-FV for the assembly station responsive to at least one or any combination of more than one of the QoP-FV, a different QoP-FV generated for the assembly station, and/or a QoP-FV generated for another of the plurality of assembly stations.

12. The system according to claim 1 wherein the at least one processing system comprises instructions executable to modify the instructions to generate the QoP-FV for the assembly station responsive to at least one or any combination of more than one of the assembly station image, a different assembly station image acquired for the assembly station, and/or an assembly station image acquired for another of the plurality of assembly stations.

13. The system according to claim 1 wherein the at least one processing system comprises instructions executable to generate a control signal for causing a modification of at least one assembly line equipment comprised in the assembly line station responsive to to at least one or any combination of more than one of the assembly station image, the QoP-FV, an assembly station image acquired for another of the plurality of assembly stations, and/or a QoP-FV generated by the processing system for another of the plurality of assembly stations.

14. The system according to claim 13 wherein the modification comprises a change in an intrinsic or extrinsic parameter of an imaging system of an assembly station of the plurality of assembly stations.

15. The system according to claim 13 wherein the plurality of assembly stations comprises a pick and place (P&P) assembly station, and the modification comprises a change in a rate of pick and place operations of the P&P assembly station of the plurality of assembly stations.

16. The system according to claim 13 wherein the plurality of assembly stations comprises a reflow oven and the modification comprises a change in an operating temperature of the oven.

17. The system according to claim 13 wherein the PCBA assembly line comprises a controller configured to use the real-time control signal to effectuate the modification and the controller and at least one processing system are configured to communicate and transmit the control signal from the at least one processing system to the controller.

18. The system according to claim 17 wherein the at least one processing system and the controller are configured to respectively generate and use the control signal to effectuate the modification before the PCBA moves along the assembly line arrives at the at least one assembly line equipment.

19. The system according to claim 1 wherein the real-time indication provided by the real-time component is accessible within a time lapse from a time of acquisition of the assembly station image processed to determine a value for the indication is less than a time for a PCBA that is assembled by the assembly line to traverse from a first to a last assembly station of the assembly line.

20. The system according to claim 1 wherein the time lapse is less than a time for the PCBA to traverse to a second assembly station from a first assembly station from which the second assembly station receives the PCBA and wherein at least one of the first and second assembly stations is neither the first nor the last assembly station of the PCBA assembly line.

21. The system according to claim 20 wherein the time lapse is less than a time it takes to traverse an assembly station of the plurality of assembly stations.

22. The system according to claim 20 wherein the time lapse is less than a time it takes a pick and place (P&P) robot in the PCBA assembly line to take an electronic component from a packaging unit (PU) and place the component on the PCBA.

23. The system according to claim 20 wherein the time lapse is less than 5 milliseconds.
